(19) United States
(12) Patent Application Publication
(10) Pub. No.: US 2020/0091258 A1
(43) Pub. Date: Mar. 19, 2020

(54) DISPLAY DEVICE, DISPLAY DEVICE PRODUCTION METHOD, DISPLAY DEVICE PRODUCTION APPARATUS, AND CONTROLLER

(71) Applicant: Sharp Kabushiki Kaisha, Sakai City, Osaka (JP)

(72) Inventors: Tohru OKABE, Sakai City (JP); Hiroki TANIYAMA, Sakai City (JP); Ryosuke GUNJI, Sakai City (JP); Shinsuke SAIDA, Sakai City (JP); Hiroharu JINMURA, Yonago-shi (JP); Yoshihiro NAKADA, Yonago-shi (JP); Akira INOUE, Yonago-shi (JP)

(21) Appl. No.: 16/497,895

(22) PCT Filed: Mar. 29, 2017
(86) PCT No.: PCT/JP2017/013039

§ 371 Date: Sep. 26, 2019

(51) Int. Cl. H01L 27/32; H01L 51/52; H01L 51/56

(52) U.S. Cl. CPC H01L 27/3246; H01L 51/5253; H01L 2227/323; H01L 51/56; H01L 51/5218; H01L 27/3276

(57) ABSTRACT

A display device configured so that a light-emitting element layer (5) is provided so as to include, in an active region (DA), a first electrode (22), an EL layer (24), and a second electrode (25), the display device including an inorganic insulating film (23) which covers an edge of the first electrode.

### TECHNICAL FIELD

The present invention relates to a display device.

### BACKGROUND ART

Patent Literature 1 discloses a subpixel structure which is included in an organic EL panel and which includes (i) banks covering edges of lower electrodes, (ii) organic layers (including a light emission layer) provided in the banks, and (iii) an lower electrode covering the organic layer.

### CITATION LIST

### Patent Literature

[Patent Literature 1]

Japanese Patent Application Publication Tokukai No. 2016-18849 (Publication date: Feb. 1, 2016)

### SUMMARY OF INVENTION

### Technical Problem

According to the configuration disclosed in Patent Literature 1, there is such a risk that a foreign matter such as moisture enters the subpixel structure from above or below the banks, so as to adversely affect the light emission layer.

### Solution to Problem

A display device in accordance with an aspect of the present invention is a display device in which a light-emitting element is provided so as to include, in an active region, a first electrode, an EL layer, and a second electrode, the display device including: a first inorganic insulating film which covers an edge of the first electrode.

### Advantageous Effects of Invention

With an aspect of the present invention, a first inorganic insulating film covering an edge of a first electrode can serve as a bank, so that it is possible to effectively prevent a foreign matter such as moisture from entering an EL layer.

### BRIEF DESCRIPTION OF DRAWINGS

FIG. 1 is a flowchart showing an example of a method of producing a display device.

FIG. 2 is a set of cross-sectional views showing an example of a configuration (active region) of a display device in accordance with the present embodiment.

FIG. 3 is a cross-sectional view showing an example of a configuration (non-active region) of a display device in accordance with Embodiment 1.

FIG. 4 is a flowchart illustrating steps involved in forming a light-emitting element layer in accordance with Embodiment 1.

FIG. 5 is a set of cross-sectional views showing an example of an effect of the display device in accordance with Embodiment 1.

FIG. 6 is a block diagram illustrating a configuration of a display device production apparatus in accordance with the present embodiment.

FIG. 7 is a flowchart illustrating steps involved in forming a light-emitting element layer in accordance with Embodiment 2.

FIG. 8 is a process cross-sectional view illustrating steps in involved in forming the light-emitting element layer in accordance with Embodiment 2.

FIG. 9 is a set of cross-sectional views showing an example of a configuration (non-active region) of a display device in accordance with Embodiment 2.

FIG. 10 is a process cross-sectional view showing an example of a variation of the steps illustrated in FIG. 8 involved in forming the light-emitting element layer.

### DESCRIPTION OF EMBODIMENTS

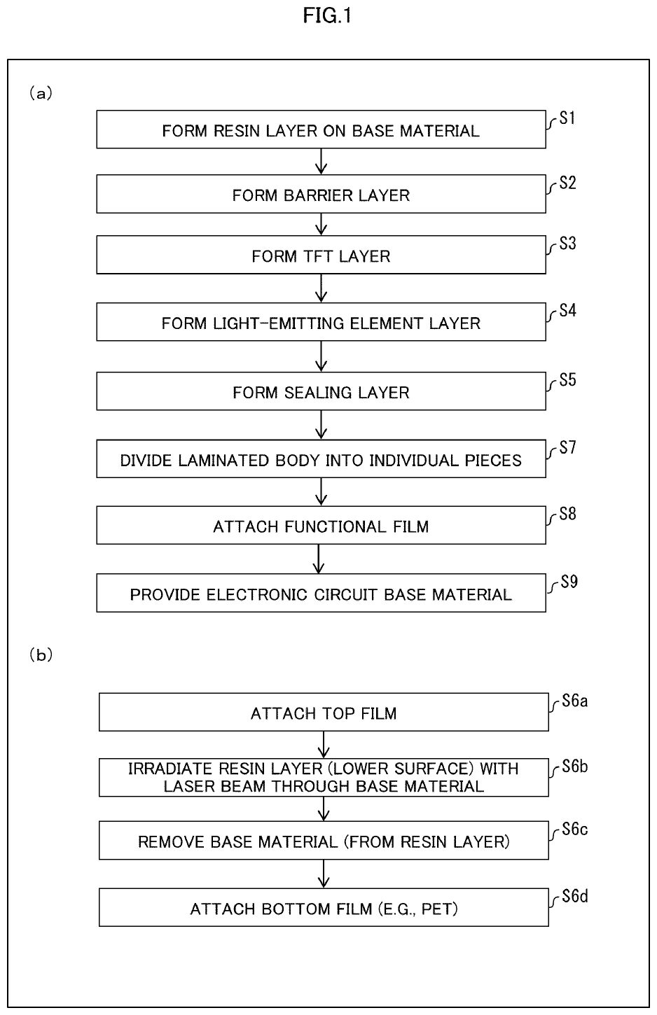

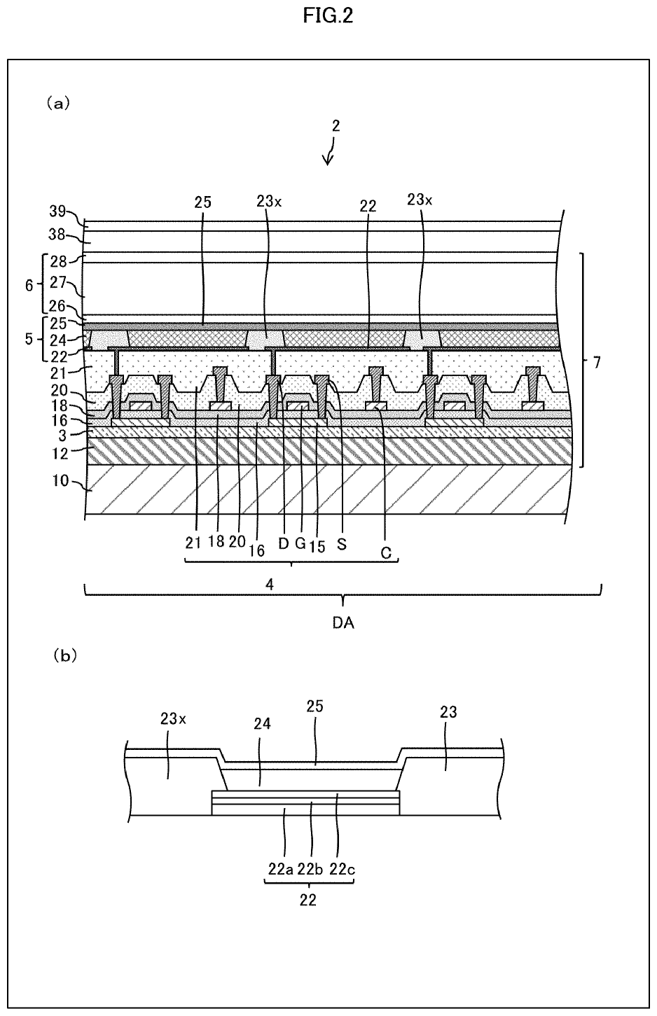

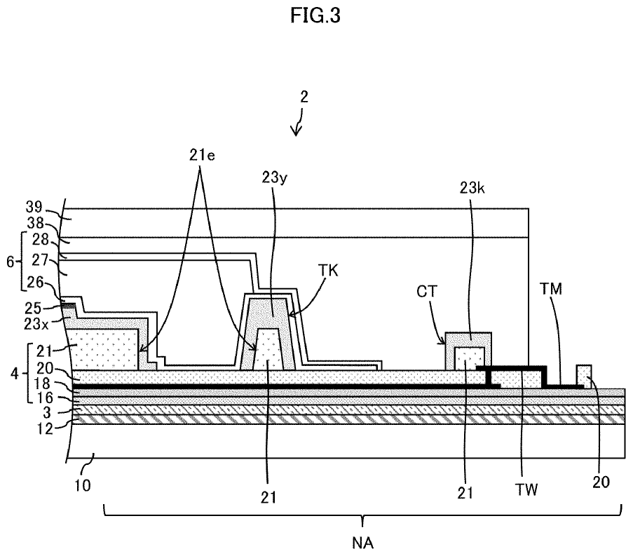

FIG. 1 is a flowchart showing an example of a method of producing a display device. (a) of FIG. 2 is a cross-sectional view showing an example of a configuration of a display device in accordance with Embodiment 1. (b) of FIG. 2 is a cross-sectional view showing an example of a configuration of a first electrode. FIG. 3 is a cross-sectional view showing an example of a configuration (non-active region) of a display device in accordance with Embodiment 1.

As illustrated in (a) of FIG. 1 and in FIG. 2, a resin layer 12 is first formed on a base material 10 (Step S1). Next, a barrier layer 3 is formed (Step S2). Next, a TFT layer 4, which includes a gate insulating film 16, passivation films 18 and 20, and an organic planarizing film 21, is formed (Step S3). Next, a light-emitting element layer (such as an OLED element layer) 5 is formed (Step S4). Next, a sealing layer 6, which includes inorganic sealing films 26 and 28 and an organic sealing film 27, is formed, so that a laminated body 7 is formed (Step S5). Next, the laminated body 7 together with the base material 10 is divided into individual pieces (Step S7). Next, functional films 39 are attached to respective pieces via adhesive layers 38 (Step S8). Next, at respective end parts of the TFT layers 4, electronic circuit boards are provided (Step S9). This causes a display device 2 illustrated in FIG. 2 to be obtained. Note that each of the steps above is carried out by a production apparatus for producing the display device.

In a case where a flexible display device is to be produced, as illustrated in (b) of FIG. 1 and in FIG. 2, the laminated body 7 is provided on a glass substrate, and then a top film is attached onto the laminated body 7 via the adhesive layer (Step S6a). Next, a lower surface of the resin layer 12 is irradiated with a laser beam through the glass substrate (Step S6b). In this step, the lower surface of the resin layer 12 (i.e., an interface with the glass substrate 10) changes in quality due to abrasion. This causes a binding force between the resin layer 12 and the glass base material to be reduced. Next, the glass substrate is removed from the resin layer 12 (Step S6c). Next, the base material 10 (such as a bottom film made of, for example, PET) is attached to the lower surface of the resin layer 12 via the adhesive layer (Step S6d). Subsequently, the process proceeds to Step S7.

The resin layer 12 is made of a material, examples of which encompass polyimide, epoxy, and polyamide. The bottom film 10 is made of a material, examples of which encompass polyethylene terephthalate (PET).

The barrier layer 3 is a layer for preventing moisture and impurities from reaching the TFT layers 4 or the light-emitting element layer 5 while the display device is being used. The barrier layer 3 can be configured by, for example, (i) a silicon oxide film formed by CVD, (ii) a silicon nitride film formed by CVD, (iii) a silicon oxynitride film formed by CVD, or (iv) a laminated film made up of these films. The inorganic barrier layer 3 has a thickness of, for example, 50 nm to 1500 nm.

The TFT layers 4 each include (i) a semiconductor film 15, (ii) the gate insulating film 16 provided on an upper side of the semiconductor film 15, (iii) gate electrodes G provided on an upper side of the gate insulating film 16, (iv) the passivation films 18 and 20 provided on upper sides of the gate electrodes G, (v) capacitor electrodes C and terminals TM which are provided on an upper side of the passivation film 18, (vi) source electrodes S and drain electrodes D provided on the upper side of the passivation film 20, and (vii) the organic planarizing film 21 provided on upper sides of the source electrode S and of the drain electrodes D. The semiconductor film 15, the gate insulating film 16, the gate electrodes G, the passivation films 18 and 20, the source electrodes S, and the drain electrodes D together constitute thin film transistors (TFT). In a non-active region (i.e., a region which does not overlap the light-emitting element layer 5) of the TFT layer 4, a plurality of terminals TM are provided so as to be used for connecting the TFT layer 4 to an IC chip and to an electronic circuit board such as an FPC. Edges of the terminals TM are covered with the passivation film 20.

The semiconductor film 15 is made of, for example, low-temperature polysilicon (LTPS) or oxide semiconductor. The gate insulating film 16 can be configured by, for example, (i) a silicon oxide (SiOx) film formed by a CVD method, (ii) a silicon nitride (SiNx) film formed by a CVD method, or (iii) a laminated film made up of the silicon oxide film and the silicon nitride film. The gate electrode G, the source electrode S, the drain electrode D, and the terminals are each constituted by, for example, a single-layer film made of a metal containing at least one of aluminum (Al), tungsten (W), molybdenum (Mo), tantalum (Ta), chrome (Cr), titanium (Ti), and copper (Cu), or alternatively constituted by a laminated film of metals including at least one of these metals. Note that FIG. 2 shows that the TFT, having the semiconductor film 15 as a channel, has a top-gate structure. Alternatively, the TFT can have a bottom-gate structure (for example, in a case where the channel of the TFT is an oxide semiconductor).

The gate insulating film 16 and the passivation films 18 and 20 can be configured by, for example, (i) a silicon oxide (SiOx) film formed by a CVD method, (ii) a silicon nitride (SiNx) film formed by a CVD method, or (iii) a laminated film made up of the silicon oxide film and the silicon nitride film. The organic planarizing film 21 can be made of, for example, a photosensitive organic material, such as polyimide or acrylic, which can be used for coating.

The light-emitting element layer 5 (e.g., organic light-emitting diode layer) includes (i) first electrodes 22 (e.g., anode) provided on an upper side of the organic planarizing film 21, (ii) first inorganic insulating films 23x defining subpixels of an active region DA (display region), (iii) EL (electroluminescence) layers 24 provided on upper sides of the first electrode 22, and (iv) a second electrode 25 provided on upper sides of the EL layers 24. The first electrodes 22, the EL layers 24, and the second electrode 25 together form light-emitting elements (e.g., organic light-emitting diodes).

The first inorganic insulating films 23x can be formed by, for example, patterning, by a photolithography method, an inorganic film containing at least one of a silicon nitride film, a silicon oxynitride film, and a silicon oxide film, any of which is formed by a CVD method. Alternatively, the first inorganic insulating films 23x can be formed by patterning, by a photolithography method, a photosensitive, inorganic SOG (spin-on glass) material which has been applied. The first inorganic insulating films 23x serve as banks (pixel partition walls) covering the edges of the first electrodes 22.

In the non-active region NA, a protruding structure (droplet stopper) TK is provided. The protruding structure TK defines edges of the organic sealing film 27 (formed by, for example, an inkjet method). The protruding structure TK is configured so as to include the organic planarizing film 21 and a second inorganic insulating film 23y covering the organic planarizing film 21. The first inorganic insulating film 23x and the second inorganic insulating film 23y are formed in one layer (i.e., formed in one process).

The EL layers 24 are formed, by a deposition method or an inkjet method, in a region (subpixel region) surrounded by partition walls 23c. In a case where the light-emitting element layer 5 is an organic light-emitting diode (OLED) layer, the EL layer 24 is made up of, for example, a hole injection layer, a hole transfer layer, a light emission layer, an electron transfer layer, and an electron injection layer which are disposed in order from the bottom.

The first electrodes (anodes) 22 are each made up of, for example, a layer of indium tin oxide (ITO) and a layer of an Ag-containing alloy. The first electrode 22 has light reflectivity. The second electrode (e.g., cathode) 25 is a common electrode, and can be made of a transparent metal such as indium tin oxide (ITO) or indium zincum oxide (IZO).

In a case where the light-emitting element layer 5 is an OLED layer, a driving electric current between the first electrodes 22 and the second electrode 25 causes a hole and an electron to recombine with each other in the EL layer 24. By a resultant exciton reaching a ground state, light is emitted.

The present invention is not limited to an example in which the light-emitting element layer 5 constitutes OLED elements. Alternatively, the light-emitting element layer 5 can constitute inorganic light-emitting diodes or quantum-dot light-emitting diodes.

The sealing layer 6 includes (i) a first inorganic sealing film 26 covering the first inorganic insulating film 23x, the second inorganic insulating film 23y, and the second electrode 25, (ii) an organic sealing film 27 covering the first inorganic sealing film 26, and (iii) a second inorganic sealing film 28 covering the organic sealing film 27.

The first inorganic sealing film 26 and the second inorganic sealing film 28 can each be configured by, for example, (i) a silicon oxide film formed by CVD, (ii) a silicon nitride film formed by CVD, (iii) a silicon oxynitride film formed by CVD, or (iv) a laminated film made up of these films. The organic sealing film 27 is a light-transmissive organic insulating film, and is thicker than each of the first inorganic sealing film 26 and the second inorganic sealing film 28. The organic sealing film 27 can be made of, for example, a photosensitive organic material, such as polyimide or acrylic, which can be used for coating. For example, the first inorganic sealing film 26 is coated, by inkjet coating, with ink containing such an organic material, and then the ink is cured by irradiation with an ultraviolet ray. The sealing layer 6 covers the light-emitting element layer 5 so as to prevent the light-emitting element layer 5 from being permeated with a foreign matter such as water or oxygen.

The functional films 39 each have, for example, an optical compensation function, a touch sensor function, and/ or a protection function. The electronic circuit board is, for example, an IC chip or a flexible printed circuit board, any of which is provided on the plurality of terminals TM.

### Embodiment 1

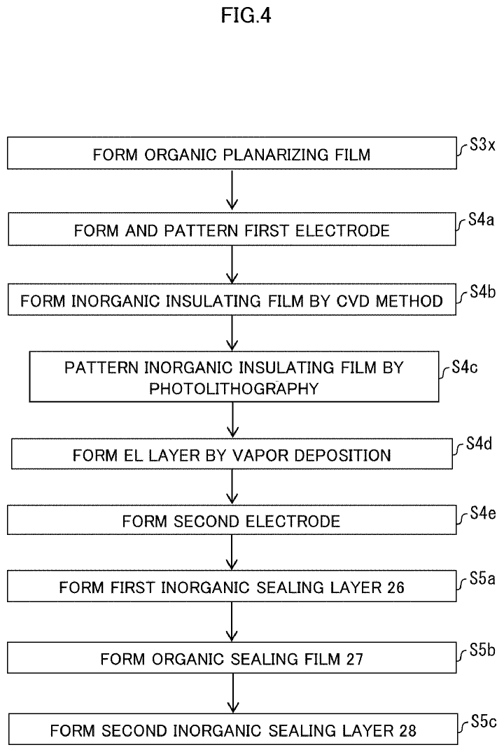

FIG. 4 is a flowchart illustrating steps involved in forming a light-emitting element layer. As illustrated in FIGS. 2 through 4, in Step S3x illustrated in FIG. 4, an organic planarizing film 21 serving as a foundation of the EL element layer 5 is formed. In this step, in the non-active region NA, respective base portions of the protruding structure TK and of the covering member CT are each formed by an organic planarizing film 21.

Next, on the organic planarizing films 21, first electrodes 22 are formed and patterned (Step S4a). The first electrodes 22 are formed in the form of islands, and have light reflectivity. As illustrated in (b) of FIG. 2, each of the first electrodes 22 includes a base film 22a, a light reflective film 22b, and a light transmissive film 22c, each of which is electrically conducive. Note that the base film 22a and the light transmissive film 22c are each made of, for example, ITO.

Next, an inorganic insulating film (such as a single film made of silicon nitride, silicon oxide, silicon oxynitride, SiCO, or SiCN, or a laminated film containing at least two of these materials) is provided in a layer higher than the first electrodes 22 by a chemical vapor deposition (CVD) method (Step S4b). Next, the inorganic insulating film is patterned by photolithography (Step S4c).

As a result, a first inorganic insulating films 23x, which serve as banks covering edges of the first electrodes 22 in the form of islands, are formed. Note that non-edge parts at the upper surfaces of first electrodes 22 are exposed without being covered with the first inorganic insulating films 23x. In Step S4c, in a non-active region NA, the following are formed: (i) a second inorganic insulating film 23y which covers the upper surface and the end surface of a base portion (organic planarizing film 21) of the protruding structure TK and (ii) a fourth inorganic insulating film 23k which covers the upper surface and the end surface of a base portion (organic planarizing film 21) of the covering member CT.

Next, an EL layer 24 is formed by vapor deposition (Step S4d). This (i) causes the EL layers 24 to be provided along the inner surfaces (inclined surfaces) of the banks constituted by the first inorganic insulating films 23x and (ii) causes the non-edge part of the upper surface (ITO) of the first electrodes 22 to be in contact, at the bottom surfaces of the banks, with the EL layers 24.

Next, the second electrode is formed by sputtering or the like with use of a mask (Step S4e). This allows a light-emitting element (EL element), which includes the first electrode 22, the first inorganic insulating film 23x, the EL layer 24, and the second electrode 25, to be provided in each of a plurality of subpixels in the active region. Note that the second electrode is a so-called a solid electrode, and is shared by the plurality of subpixels.

Next, a first inorganic sealing layer 26 is formed, by patterning, by use of a CVD method in which a mask is used (Step S5a). Next, an organic sealing layer 27 is formed by coating by use of an inkjet method (Step S5b). Next, a second inorganic sealing layer 28 is formed, by patterning, by use of a CVD method in which a mask is used (Step S5c).

The first inorganic sealing film 26 is formed so as to cover the upper surface and both the end surfaces of the protruding structure TK. In addition, the second inorganic sealing film 28 is formed so as to cover, via the first inorganic sealing film 26, (i) the upper surface of the protruding structure TK and (ii) the external (edge side of the display device) end surface of the protruding structure TK. In addition, an edge of the organic sealing film 27 is formed so as to (i) overlap the protruding structure TK or (ii) be located closer to the inner side (active region side) than is the protruding structure TK. Surfaces (the upper surface and the end surfaces) of the protruding structure TK is formed by the second inorganic insulating film 23y. In addition, parts 21e, which overlap the organic sealing film 27 at the end surfaces of the organic planarizing films 21, are covered with the first inorganic insulating film 23x or with the second inorganic insulating film 23y.

Step S5a (in which the first inorganic sealing layer 26 is formed) and Step S5c (in which the second inorganic sealing film 28 is formed) are carried out at temperatures (e.g., not more than 100°) lower than a temperature at which Step S4b (in which the first inorganic insulating films 12x covering the first electrodes 22 are formed) is carried out.

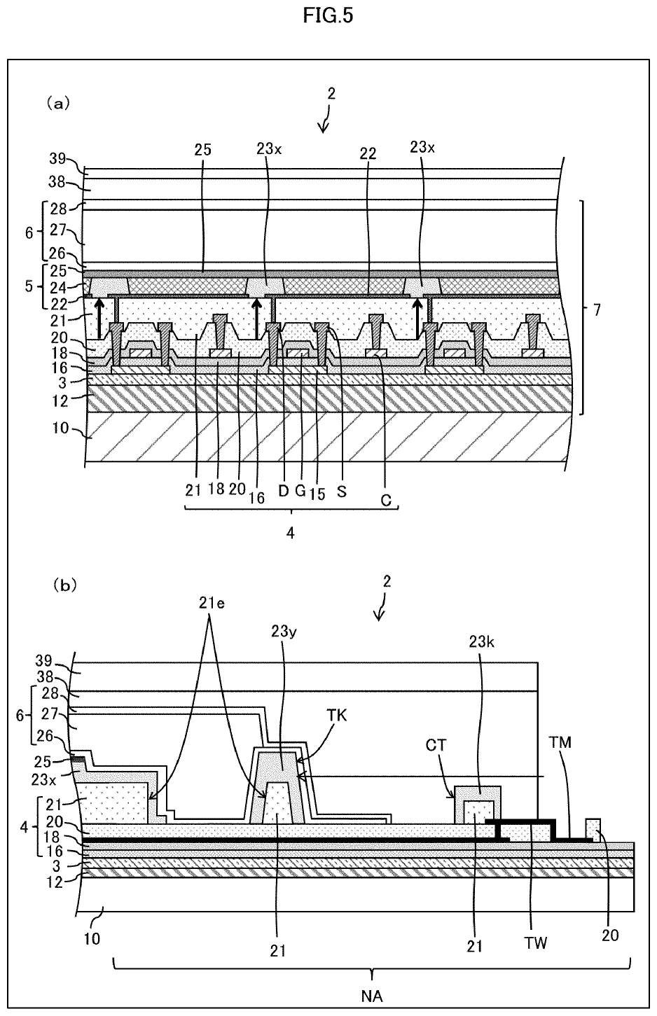

The display device in accordance with Embodiment 1 is configured so that it is possible to block, by the first inorganic insulating films 23x, foreign matters (e.g., moisture) which enter a pixel part through paths such as those indicated by arrows illustrated in (a) of FIG. 5. In addition, it is also possible to block, by the second inorganic insulating film 23y, foreign matters (e.g., moisture) which enter the protruding structure TK through a path such as that indicated by an arrow illustrated in (b) of FIG. 5.

In addition, it is possible to reduce production costs in comparison with a case where banks covering the edges of the first electrodes are each made of a costly organic material such as polyimide. The first inorganic insulating films 23x and the second inorganic insulating films 23y are formed before the step of vapor deposition of the EL layers 24. This allows the first inorganic insulating films 23x and the second inorganic insulating films 23y to be formed at a high temperature (not less than 200°), and therefore makes it possible to obtain films which are dense so as to have high barrier performance.

In addition, parts 21e, which overlap the organic sealing film 27 at the end surfaces of the organic planarizing films 21, are covered with the first inorganic insulating film 23x or with the second inorganic insulating film 23y. The inorganic sealing films 26 and 28, which are formed at a low temperature (e.g., approximately 80° to 120°) by CVD, have poor coverage characteristics. This may prevent the inorganic sealing films 26 and 28 from easily climbing over steps of the organic planarizing film 21 (planarizing film). However, the first inorganic insulating films 23x and the second inorganic insulating films 23y, which are formed at a high temperature (e.g., approximately 300° to 350°) by CVD, have good coverage characteristics. This allows the first inorganic insulating films 23x and the second inorganic insulating films 23y to easily climb over such steps. It is therefore possible to increase sealing performance.

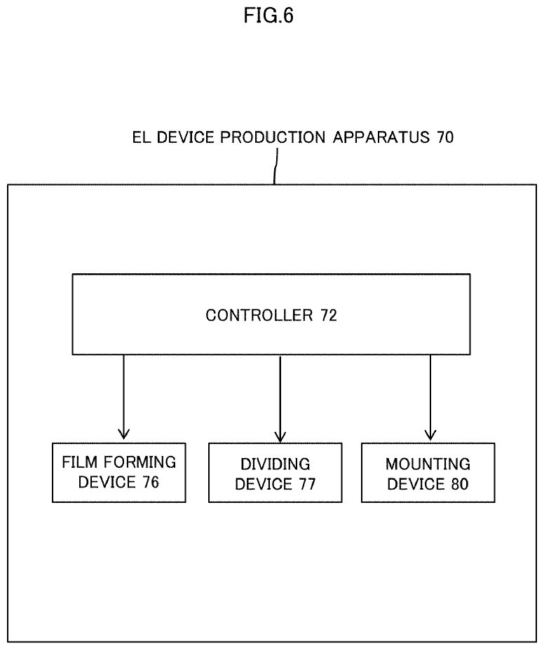

FIG. 6 is a block diagram illustrating a configuration of the display device production apparatus in accordance with Embodiment 1. As illustrated in FIG. 6, a display device production apparatus 70 includes (i) a film forming device 76, (ii) a dividing device 77, (iii) a mounting device 80, and (iv) a controller 72 for controlling these devices. In response to the control by the controller 72, the film forming device 76 carries out Steps S4a through S4e illustrated in FIG. 4.

### Embodiment 2

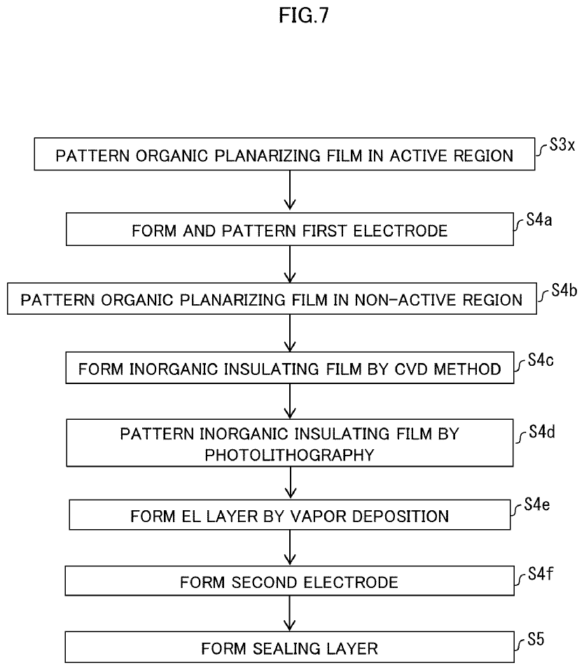

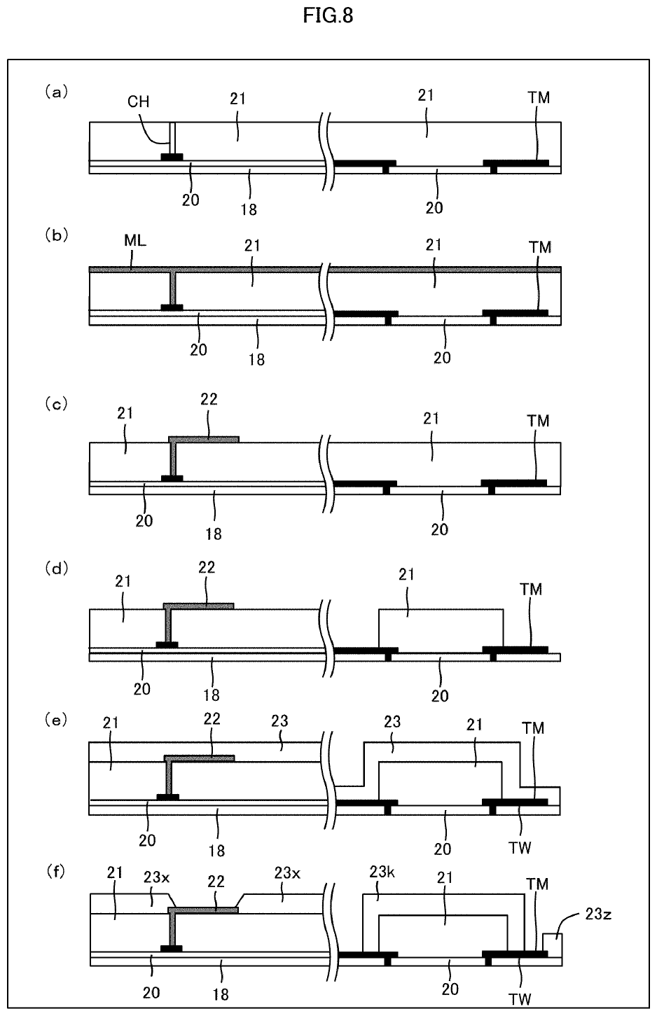

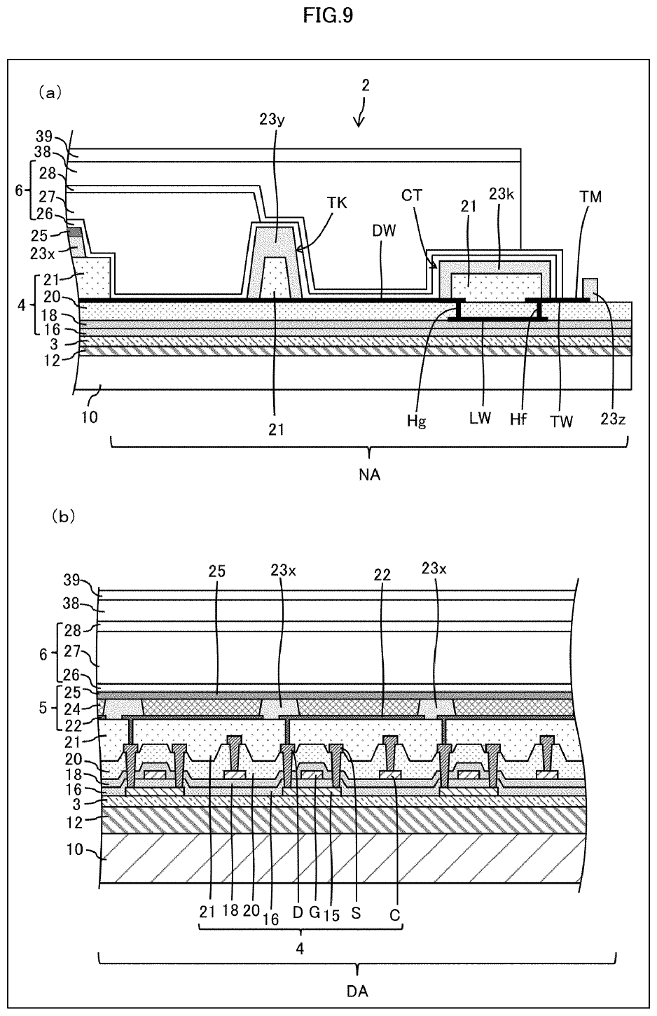

FIG. 7 is a flowchart illustrating steps involved in forming a light-emitting element layer in accordance with Embodiment 2. FIG. 8 is a process cross-sectional view illustrating steps in involved in forming the light-emitting element layer in accordance with Embodiment 2. FIG. 9 is a set of cross-sectional views showing examples of a configuration of a display device in accordance with Embodiment 2.

According to Embodiment 2, Step S3x is carried out so as to (A) form an organic planarizing film 21 which serves as a foundation of a pixel part and which covers a terminal TM in a non-active area and (B) form a contact hole CH (for connecting a first electrode and a TFT) in the organic planarizing film 21 in an active region (see FIG. 7 and (a) of FIG. 8). In this step, (unlike the step illustrated in FIG. 3) formation of the terminal TM and formation of a source electrode S and a drain electrode D of the TFT are carried out in one process (i.e., in one layer). The terminal TM has, for example, a laminated structure in which an aluminum (Al) film is sandwiched with two layers of titanium (Ti) film.

Next, as illustrated in FIG. 7 and (b) and (c) of FIG. 8, an electrode material ML (e.g., an electrically conducive laminated film including an ITO layer, a silver alloy layer, and an ITO layer) is formed and then patterned so as to form a first electrode 22 (S4a). Note that since the terminal TM is covered with the organic planarizing film 21, the terminal TM is not subject to damage during etching of the first electrode 22.

Next, as illustrated in FIG. 7 and (d) of FIG. 8, the organic planarizing film 21 in the non-active region is patterned. This causes respective base portions of a protruding structure TK and of a covering member CT illustrated in (a) of FIG. 9 to be formed, and causes the organic planarizing film 21 on the terminal TM to be removed. Note that a terminal wire TW has (A) one end part which is formed so as to be continuous with the terminal TM and (B) the other end part which is covered with the base portion (organic planarizing film 21) of the covering member CT.

Next, as illustrated in FIG. 7 and (e) of FIG. 8, an inorganic insulating film 23 is formed so as to cover (A) the first electrode 22, (B) base portions of the protruding structure TK and the covering member CT, and (C) the terminal TM.

Next, as illustrated in FIG. 7 and (f) of FIG. 8, the inorganic insulating film 23 is patterned. This, in the active region, causes a bank (pixel partition wall) to be formed by the first inorganic insulating film 23x. In the non-active region, as illustrated in (a) of FIG. 9, the following are formed: (A) a second inorganic insulating film 23y covering the base of the protruding structure TK and (B) a fourth inorganic insulating film 23k covering the base (organic planarizing film 21) of the covering member CT. Furthermore, because part of the inorganic insulating film 23 covering the terminal TM is removed in the non-active region, part of an upper surface of the terminal TM is exposed, so that a third inorganic insulating film 23z covering an end surface of the terminal TM is formed.

Specifically, the first inorganic insulating film 23x, the second inorganic insulating film 23y, the third inorganic insulating film 23z, and the fourth inorganic insulating film 23k are formed in one process (i.e., formed and patterned).

In addition, in the example shown in FIG. 9, on the terminal wire TW which is formed so as to be continuous with the terminal TM, the following are disposed: (A) the covering member CT (the organic planarizing film 21 and the fourth inorganic insulating film 23k covering the organic planarizing film 21), (B) the first inorganic sealing layer 26, and (C) the second inorganic sealing layer 28. An edge of the adhesive layer 38 overlaps the fourth inorganic insulating film 23k.

The terminal wire TW is connected to a relay wire LW via a contact hole Hf which overlaps the covering member CT. The contact hole Hf passes through the inorganic insulating film 20. The relay wire LW is provided in a layer in which a capacitor wire C is provided (i.e., the relay wire LW is provided on the inorganic insulating film 18). The relay wire LW is connected to a drawing wire DW (which is drawn out from the active region DA of the TFT layer 4) via a contact hole Hg (which is formed closer to the active region DA than is the contact hole Hf). The contact hole Hg passes through the inorganic insulating film 20. The drawing wire DW is provided in a layer in which the terminal wire TW, a source wire S, and a drawing wire D are provided (i.e., the drawing wire DW is provided on the inorganic insulating film 20).

According to Embodiment 2, the terminal TM is covered with the organic planarizing film 21 while the first electrode 22 is being formed. This prevents the terminal TM from being subject to damage by an etchant. In addition, the terminal TM can be configured so that the edge of the terminal TM is covered with the third inorganic insulating film 23z (which is thinner than the organic film). This allows the terminal TM to be provided on, for example, an IC chip or an FPC with increased reliability.

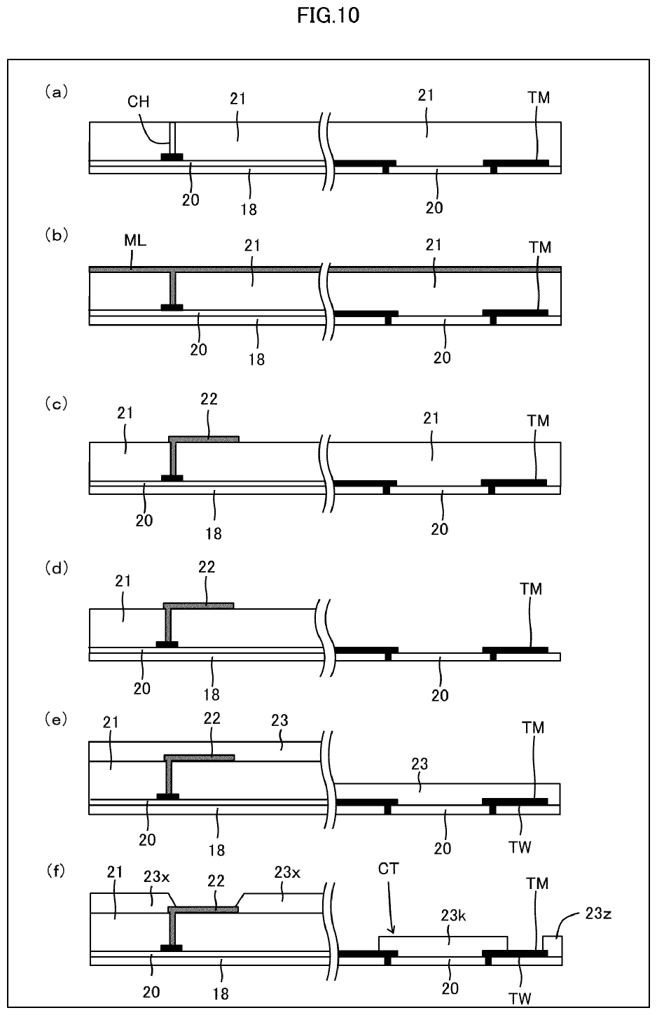

Note that (d) of FIG. 8 and (a) of FIG. 9 show examples in which the base portions of the protruding structure TK and of the covering member CT are formed by the organic planarizing film 21. However, the present invention is not limited to such examples. Alternatively, it is possible to remove the organic planarizing film 21 in the non-active region as illustrated in (d) of FIG. 10, so that the covering member CT is formed merely by the fourth inorganic insulating film 23k as illustrated in (f) of FIG. 10.

An electro-optic element included in a display device in accordance with Embodiment 3 is not limited to any particular one. Examples of the display device encompass (i) an organic electro luminescence (EL) display including an organic light emitting diode (OLED) as an electro-optic element, (ii) an inorganic EL display including an inorganic light-emitting diode as an electro-optic element, and (iii) a QLED display including a quantum dot light emitting diode (QLED) as an electro-optic element.

Aspects of the present invention can also be expressed as follows:

Aspect 1: A display device in which a light-emitting element layer is provided so as to include, in an active region, a first electrode, an EL layer, and a second electrode, the display device including: a first inorganic insulating film which covers an edge of the first electrode.

Aspect 2: The display device which is, for example, described in Aspect 1, configured so that an organic planarizing film is provided in a layer lower than the first inorganic insulating film.

Aspect 3: The display device which is, for example, described in Aspect 2, further including: a sealing layer including an organic sealing film and an inorganic sealing film and being configured to cover the light-emitting element layer, the organic planarizing film having an end surface which overlaps the organic sealing film and which is covered with the first inorganic insulating film.

Aspect 4: The display device which is, for example, described in Aspect 2, configured so that a protruding structure is provided in a non-active region; and at least a first part of the protruding structure is formed by a second inorganic insulating film which is provided in a layer in which the first inorganic insulating film is provided.

Aspect 5: The display device which is, for example, described in Aspect 4, configured so that at least a second part of the protruding structure is formed by the organic planarizing film.

Aspect 6: The display device which is, for example, described in Aspect 5, configured so that the protruding structure is configured so that an upper surface of the organic planarizing film is covered with the second inorganic insulating film.

Aspect 7: The display device which is, for example, described in Aspect 6, configured so that the protruding structure is configured so that at least part of an end surface of the organic planarizing film is covered with the second inorganic insulating film.

Aspect 8: The display device which is, for example, described in any one of Aspects 4 through 7, further including: a sealing layer including an organic sealing film and an inorganic sealing film and being configured to cover the light-emitting element layer, the inorganic sealing film covering an upper surface and an external end surface of the protruding structure.

Aspect 9: The display device which is, for example, described in Aspect 8, configured so that the organic sealing film has an edge which (i) overlaps the protruding structure or (ii) is located closer to an inner side than is the protruding structure.

Aspect 10: The display device which is, for example, described in Aspect 9, configured so that a surface of the protruding structure is formed by the second inorganic insulating film.

Aspect 11: The display device which is, for example, described in any one of Aspects 1 through 10, configured so that: a terminal is provided in a non-active region; and an end surface of the terminal is covered with a third inorganic insulating film which is provided in a layer in which the first inorganic insulating film is provided.

Aspect 12: The display device which is, for example, described in Aspect 11, further including: a TFT which is provided in the active region so as to be electrically connected to the first electrode, the terminal being provided in a layer in which a conductive electrode of the TFT is provided.

Aspect 13: The display device which is, for example, described in Aspect 11 or 12, further including: a terminal wire having one end part which is formed so as to be continuous with the terminal, the terminal wire having the other end part which is covered with a covering member.

Aspect 14: The display device which is, for example, described in Aspect 13, configured so that at least part of the covering member is formed by a fourth inorganic insulating film provided in a layer in which the first inorganic insulating film is provided.

Aspect 15: The display device which is, for example, described in any one of Aspects 1 through 14, configured so that the first inorganic insulating film is made of silicon nitride or a photosensitive inorganic SOG material.

Aspect 16: The display device which is, for example, described in any one of Aspects 1 through 15, configured so that the first electrode includes a base film, a light reflective film, and a light transmissive film, each of which is electrically conducive.

Aspect 17: The display device which is, for example, described in Aspect 16, configured so that the base film and the light transmissive film are each made of ITO.

Aspect 18: The display device which is, for example, described in any one of Aspects 1 through 17, configured so that the first inorganic insulating film forms a bank by which pixels are isolated from each other.

Aspect 19: The display device which is, for example, described in Aspect 18, configured so that the first electrode is an anode of an OLED.

Aspect 20: The display device which is, for example, described in Aspect 18 configured so that the EL layer is configured to be in contact with an upper surface of the first electrode.

Aspect 21: The display device which is, for example, described in Aspect 20, configured so that the EL layer is configured to cover an inclined surface inside the bank.

Aspect 22: A display device production method of producing a display device, the display device being configured so that a light-emitting element layer is provided so as to include, in an active region, a first electrode, an EL layer, and a second electrode, the method including the step of: forming a first inorganic insulating film which covers an edge of the first electrode.

Aspect 23: The display device production method which is, for example, described in Aspect 22, further including the step of: forming an organic planarizing film in a layer lower than the first inorganic insulating film.

Aspect 24: The display device production method which is, for example, described in Aspect 23, further including the step of: forming a protruding structure in a non-active region, at least a first part of the protruding structure being formed by a second inorganic insulating film which is formed in a process in which the first inorganic insulating film is formed.

Aspect 25: The display device production method which is, for example, described in Aspect 24, configured so that at least a second part of the protruding structure is formed by the organic planarizing film.

Aspect 26: The display device production method which is, for example, described in Aspect 25, configured so that the protruding structure is formed so that an upper surface of the organic planarizing film is covered with the second inorganic insulating film.

Aspect 27: The display device production method which is, for example, described in Aspect 26, configured so that the protruding structure is formed so that at least part of an end surface of the organic planarizing film is covered with the second inorganic insulating film.

Aspect 28: The display device production method which is, for example, described in any one of Aspects 24 through 27, further including the step of: forming a sealing layer so that the sealing layer includes an organic sealing film and an inorganic sealing film and covers the light-emitting element layer, the inorganic sealing film covering an upper surface and an external end surface of the protruding structure.

Aspect 29: The display device production method which is, for example, described in Aspect 28, configured so that: the first inorganic insulating film, the second inorganic insulating film, and the inorganic sealing film are each formed by a CVD method; and the first inorganic insulating film and the second inorganic insulating film are each formed at a temperature higher than a temperature at which the inorganic sealing film is formed.

Aspect 30: The display device production method which is, for example, described in Aspect 23, further including the step of: forming a terminal in a non-active region, an end surface of the terminal is covered with a third inorganic insulating film which is formed in a process in which the first inorganic insulating film is formed.

Aspect 31: The display device production method which is, for example, described in Aspect 30, configured so that the first electrode is formed while the end surface of the terminal is covered with the organic planarizing film, and then the organic planarizing film covering the terminal is removed.

Aspect 32: The display device production method which is, for example, described in Aspect 30, further including the step of: forming, in the active region, a TFT which is electrically connected to the first electrode, the terminal is formed in a process which is a conductive electrode of the TFT is formed.

Aspect 33: The display device production method which is, for example, described in any one of Aspects 22 through 32, configured so that the first inorganic insulating film is formed with use of silicon nitride or a photosensitive inorganic SOG material.

Aspect 34: The display device production method which is, for example, described in Aspect 33, configured so that a surface of the first electrode is formed by ITO.

Aspect 35: A production apparatus for producing a display device, the display device being configured so that a light-emitting element layer is provided so as to include, in an active region, a first electrode, an EL layer, and a second electrode, the production apparatus being configured to form a first inorganic insulating film which covers an edge of the first electrode.

Aspect 36: A film forming device for use in production of a display device, the display device being configured so that a light-emitting element layer is provided so as to include, in an active region, a first electrode, an EL layer, and a second electrode, the film forming device being configured to form a first inorganic insulating film which covers an edge of the first electrode.

Aspect 37: A controller for controlling the film forming device which is, for example, described in Aspect 36, to form the first inorganic insulating film which covers the edge of the first electrode.

Note that the present invention is not limited to the foregoing embodiments, and the present invention also encompasses, in its technical scope, any embodiment derived by combining technical means disclosed in differing embodiments. Further, it is possible to form a new technical feature by combining the technical means disclosed in the respective embodiments.

### REFERENCE SIGNS LIST

2 Display device

4 TFT layer

5 Light-emitting element layer

6 Sealing layer

10 Base material

12 Resin layer

21 Organic planarizing film

22 First electrode

23x First inorganic insulating film

23y Second inorganic insulating film

23z Third inorganic insulating film

23k Fourth inorganic insulating film

24 EL layer

25 Second electrode

26 First inorganic sealing film

27 Organic sealing film

28 Second inorganic sealing film

70 Display device production apparatus

76 Film forming device

Tk Protruding structure

CT Covering member

1. A display device in which a light-emitting element layer is provided so as to include, in an active region,
a first electrode,
an EL layer, and
a second electrode,
said display device comprising:
a first inorganic insulating film which covers an edge of the first electrode.

2. The display device according to claim 1, wherein
an organic planarizing film is provided in a layer lower than the first inorganic insulating film.

3. The display device according to claim 2, further comprising:
a sealing layer including an organic sealing film and an inorganic sealing film and being configured to cover the light-emitting element layer,
the organic planarizing film having an end surface which overlaps the organic sealing film and which is covered with the first inorganic insulating film.

4. The display device according to claim 2, wherein:
a protruding structure is provided in a non-active region; and
at least a first part of the protruding structure is formed by a second inorganic insulating film which is provided in a layer in which the first inorganic insulating film is provided.

5. The display device according to claim 4, wherein
at least a second part of the protruding structure is formed by the organic planarizing film.

6. The display device according to claim 5, wherein
the protruding structure is configured so that an upper surface of the organic planarizing film is covered with the second inorganic insulating film.

7. The display device according to claim 6, wherein
the protruding structure is configured so that at least part of an end surface of the organic planarizing film is covered with the second inorganic insulating film.

8. The display device according to claim 4, further comprising:
a sealing layer including an organic sealing film and an inorganic sealing film and being configured to cover the light-emitting element layer,
the inorganic sealing film covering an upper surface and an external end surface of the protruding structure.

9. The display device according to claim 8, wherein
the organic sealing film has an edge which (i) overlaps the protruding structure or (ii) is located closer to an inner side than is the protruding structure.

10. The display device according to claim 9, wherein
a surface of the protruding structure is formed by the second inorganic insulating film.

11. The display device according to claim 1, wherein:
a terminal is provided in a non-active region; and
an end surface of the terminal is covered with a third inorganic insulating film which is provided in a layer in which the first inorganic insulating film is provided.

12. The display device according to claim 11, further comprising:
a TFT which is provided in the active region so as to be electrically connected to the first electrode,
the terminal being provided in a layer in which a conductive electrode of the TFT is provided.

13. The display device according to claim 11, further comprising:
a terminal wire having one end part which is formed so as to be continuous with the terminal,
the terminal wire having the other end part which is covered with a covering member.

14. The display device according to claim 13, wherein
at least part of the covering member is formed by a fourth inorganic insulating film provided in a layer in which the first inorganic insulating film is provided.

15. The display device according to claim 1, wherein
the first inorganic insulating film is made of silicon nitride or a photosensitive inorganic SOG material.

16. The display device according to claim 1, wherein
the first electrode includes a base film, a light reflective film, and a light transmissive film, each of which is electrically conducive.

17. The display device according to claim 16, wherein
the base film and the light transmissive film are each made of ITO.

18. The display device according to claim 1, wherein
the first inorganic insulating film forms a bank by which pixels are isolated from each other.

19. The display device according to claim 18, wherein
the first electrode is an anode of an OLED.

20. The display device according to claim 18, wherein
the EL layer is configured to be in contact with an upper surface of the first electrode.

21-37 (canceled)
